(19) United States
(12) Patent Application Publication
(10) Pub. No.: US 2012/0217626 A1
(43) Pub. Date: Aug. 30, 2012

(54) SEMICONDUCTOR DEVICE AND METHOD FOR MANUFACTURING SEMICONDUCTOR DEVICE

(75) Inventors: Taiji SAKAI, Kawasaki (JP); Kazukiyo Joshin, Kawasaki (JP); Tadahiro Imada, Kawasaki (JP); Nobuhiro Imaizumi, Kawasaki (JP); Keishiro Okamoto, Kawasaki (JP)

(73) Assignee: FUJITSU LIMITED, Kawasaki (JP)

(21) Appl. No.: 13/353,666

(22) Filed: Jan. 19, 2012

(30) Foreign Application Priority Data
Feb. 25, 2011 (JP) 2011-040464

(51) Int. Cl. H01L 23/495; H01L 21/58

(52) U.S. Cl. 257/666; 438/123; 257/E23.031; 257/E21.505

(57) ABSTRACT

A method for manufacturing a semiconductor device, includes: placing a seal layer including a connection conductive film on the surface so that the connection conductive film is in contact with an electrode of a semiconductor element and a lead; electrically coupling the electrode and the lead through the connection conductive film; and sealing the semiconductor element by the seal layer.

### CROSS-REFERENCE TO RELATED APPLICATIONS

This application claims the benefit of priority from Japanese Patent Application No. 2011-40464 filed on Feb. 25, 2011, the entire contents of which are incorporated herein by reference.

### FIELD

Embodiments relate to a semiconductor device and a method for manufacturing the same.

### BACKGROUND

A nitride semiconductor has features including a high saturation electron velocity, a wide band gap, and the like and, therefore, may be applied to a high-breakdown voltage and high-output semiconductor device. For example, the band gap of GaN serving as a nitride semiconductor is larger than the band gap of Si (1.1 eV) and the band gap of GaAs (1.4 eV) and is, for example, 3.4 eV, so that GaN has a high breakdown field strength. Consequently, GaN may be used as a material of a power device for a power supply to perform a high-voltage operation and produce a high output.

Related art is disclosed in Japanese Laid-open Patent Application No. 53-1859, Japanese Laid-open Patent Application No. 2005-251910, Japanese Laid-open Patent Application No. 61-288434, and Japanese Laid-open Patent Application No. 2007-12699.

### SUMMARY

According to one aspect of the embodiments, a method for manufacturing a semiconductor device, includes: placing a seal layer including a connection conductive film on the surface so that the connection conductive film is in contact with an electrode of a semiconductor element and a lead; electrically coupling the electrode and the lead through the connection conductive film; and sealing the semiconductor element by the seal layer.

Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 illustrates an exemplary manufacturing process of a semiconductor package;

FIG. 2A to FIG. 2F illustrate an exemplary manufacturing process of a semiconductor device;

FIG. 3 illustrates an exemplary compound semiconductor element;

FIG. 4 illustrates an exemplary lead frame;

FIG. 5A to FIG. 5C illustrate an exemplary formation of an auxiliary layer;

FIG. 6 illustrates an exemplary auxiliary layer;

FIG. 7A to FIG. 7G illustrate an exemplary formation of a seal layer;

FIG. 8 illustrates an exemplary seal layer;

FIG. 9A and FIG. 9B illustrate an exemplary bonding of a seal layer;

FIG. 10 illustrates an exemplary seal layer;

FIG. 11 illustrates an exemplary power supply device; and

FIG. 12 illustrates an exemplary high frequency amplifier.

### DESCRIPTION OF EMBODIMENTS

In packaging of a nitride semiconductor element, connection between electrodes is performed by a wire bonding method using a metal wire. Since a large current passes in the nitride semiconductor element, connection is performed by using a plurality of metal wires. Therefore, a process time may increase. When a long wire is used or there are many metal wire connection places, the on resistance of the nitride semiconductor element may increase and the power supply efficiency may be reduced. When connection between electrodes is performed by the wire bonding method, the package of the nitride semiconductor element may not become low-profile sufficiently.

In the drawings described below, for the sake of convenience, sizes and thicknesses may be indicated on different scales.

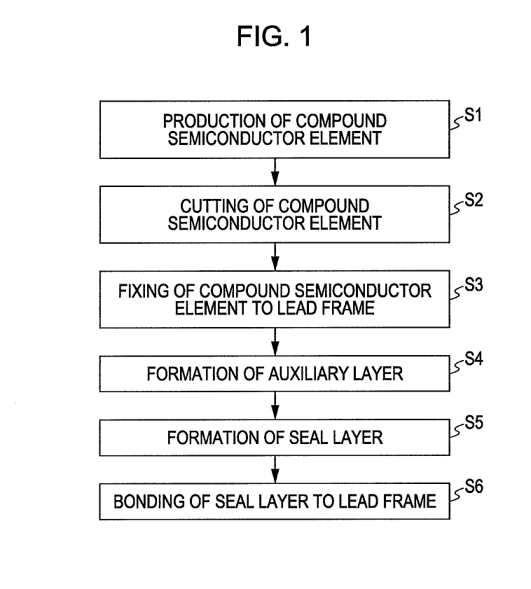

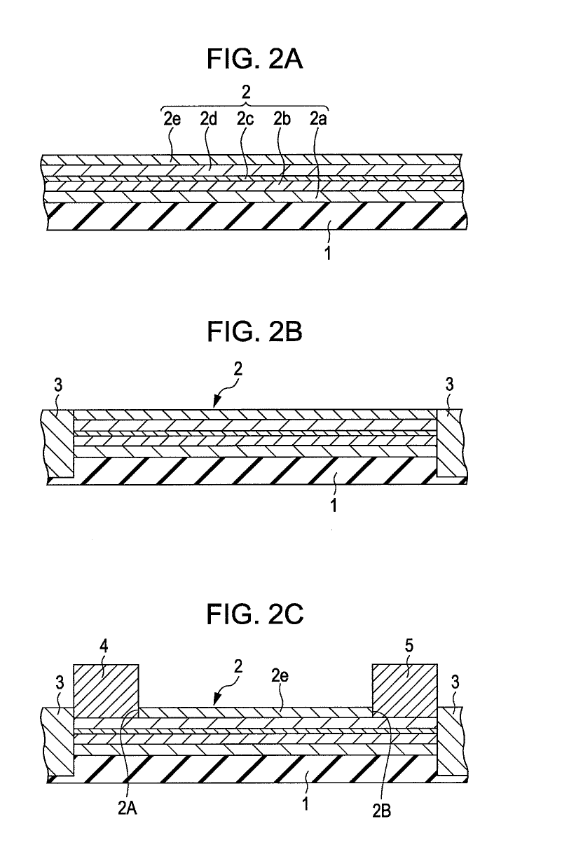

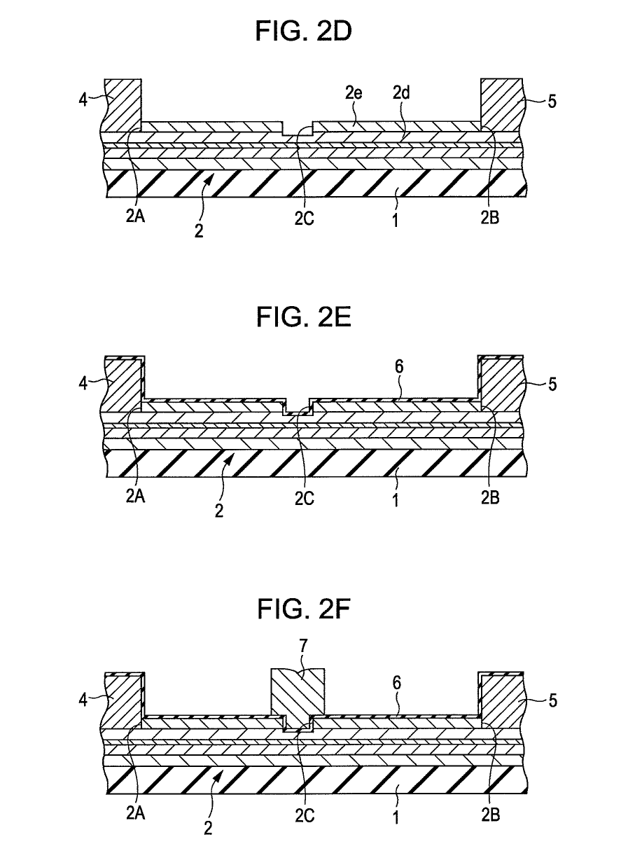

FIG. 1 illustrates an exemplary manufacturing process of a semiconductor package. FIGS. 2A to 2F illustrate an exemplary manufacturing process of a semiconductor device. In the manufacturing process of the semiconductor device illustrated in FIGS. 2A to 2F, an AlGaN/GaN HEMT may be manufactured. A compound semiconductor element is manufactured in operations S1 and S2 illustrated in FIG. 1, and a semiconductor package is manufactured through operations S3 to S6 illustrated in FIG. 1.

In the operation S1 illustrated in FIG. 1, a semiconductor element mounted on a resin circuit board, for example, a compound semiconductor element having a high electron mobility transistor (HEMT) structure is produced. For example, an AlGaN/GaN HEMT serving as a nitride semiconductor may be produced. An InAlN/GaN HEMT, an InAlGaN/GaN HEMT, or the like may be produced. Nitride semiconductor elements other than the HEMT, compound semiconductor elements other than the nitride semiconductor, semiconductor memory, or other semiconductor elements may be produced.

As illustrated in FIG. 2A, a compound semiconductor laminate structure 2 is formed on a substrate for growth, e.g., a Si substrate 1. As for the substrate for growth, a Si substrate, a SiC substrate, a sapphire substrate, a GaAs substrate, a GaN substrate, or the like may be used. Regarding the electrical conductivity, the substrate may have a semi-insulating property or an electrically conductive property. The compound semiconductor laminate structure 2 may include a buffer layer 2a, an electron transit layer 2b, an intermediate layer 2c, an electron supply layer 2d, and a cap layer 2e.

When the AlGaN/GaN HEMT is operated, a two-dimensional electron gas (2DEG) is generated in the vicinity of the interface of the electron transit layer 2b to the electron supply layer 2d, for example, the intermediate layer 2c. The 2DEG may be generated based on a difference between the lattice constant of a compound semiconductor of the electron transit layer 2b, e.g., GaN, and the lattice constant of a compound semiconductor of the electron supply layer 2d, e.g., AlGaN.

On the Si substrate 1, AlN having a film thickness of about 0.1 μm, i (intentionally undoped)-GaN having a film thickness of about 3 μm, i-AlGaN having a film thickness of about 5 nm, n-AlGaN having a film thickness of about 30 nm, and n-GaN having a film thickness of about 10 nm are formed sequentially. These compound semiconductors may be generated by, for example, a metal organic vapor phase epitaxy (MOVPE) method. A molecular beam epitaxy (MBE) method or the like may be used instead of the MOVPE method. The buffer layer 2a, the electron transit layer 2b, the intermediate layer 2c, the electron supply layer 2d, and the cap layer 2e are formed.

Regarding the growth condition of AlN, GaN, AlGaN, and GaN, a mixed gas of a trimethyl aluminum gas, a trimethyl gallium gas, and an ammonium gas may be used as the raw material gas. The presence or absence of supply and the flow rates of the trimethyl aluminum gas serving as an Al source and the trimethyl gallium gas serving as a Ga source may be specified in accordance with the growing compound semiconductor layer. The flow rate of the ammonia gas serving as the common raw material may be about 100 ccm to 10 LM. The growth pressure may be about 50 Torr to 300 Torr. The growth temperature may be about 1,000° C. to 1,200° C.

When GaN and AlGaN are generated as the n-type, for example, a SiH₄ gas including Si serving as an n-type impurity is added to the raw material gas at a certain flow rate, so that GaN and AlGaN are doped with Si. The concentration of Si doping may be about 1×10¹⁸/cm³ to about 1×10²⁰/cm³, for example, about 5×10¹⁸/cm³.

As illustrated in FIG. 2B, an element isolation structure 3 is formed. In FIG. 2C to FIG. 2F, the element isolation structure 3 may be omitted. For example, argon (Ar) is implanted into the element isolation region of the compound semiconductor laminate structure 2. The element isolation structure 3 is formed in the compound semiconductor laminate structure 2 and a surface layer portion of the Si substrate 1. An active region is delimited on the compound semiconductor laminate structure 2 with the element isolation structure 3. The element isolation may be formed by, for example, a shallow trench isolation (STI) method instead of the implantation method. Regarding dry etching of the compound semiconductor laminate structure 2, for example, a chlorine based etching gas may be used.

As illustrated in FIG. 2C, a source electrode 4 and a drain electrode 5 are formed. Electrode recesses 2A and 2B are formed at positions to be provided with the source electrode and the drain electrode on the surface of the compound semiconductor laminate structure 2. A resist is applied to the surface of the compound semiconductor laminate structure 2. The resist is processed by lithography, so that openings to expose the surface of the compound semiconductor laminate structure 2 corresponding to the positions to be provided with electrodes are formed in the resist. Consequently, a resist mask having openings is formed.

The positions to be provided with electrodes of the cap layer 2e are removed through dry etching using the resist mask until the surface of the electron supply layer 2d is exposed. The electrode recesses 2A and 2B for exposing the positions to be provided with electrodes on the surface of the electron supply layer 2d are formed. An inert gas, e.g., Ar, and a chlorine based gas, e.g., Cl₂, may be used as an etching gas. As for the etching condition, for example, the flow rate of Cl₂ is set at 30 sccm, the pressure is set at 2 Pa, and the RF input electric power is set at 20 W. The electrode recesses 2A and 2B may be formed by etching the cap layer 2e in partway or be formed by etching up to the electron supply layer 2d or more. The resist mask is removed by an ashing treatment or the like.

A resist mask to form the source electrode and the drain electrode is formed. For example, a canopy structure two-layer resist suitable for an evaporation method and a lift-off method may be used. The canopy structure two-layer resist is applied to the compound semiconductor laminate structure 2 and, thereby, the openings to expose the electrode recesses 2A and 2B are formed. Consequently, the resist mask having the openings is formed. An electrode material, e.g., Ta/Al, is deposited on the resist mask and in the openings to expose the electrode recesses 2A and 2B by, for example, the evaporation method using the resist mask. The thickness of Ta may be about 20 nm, and the thickness of Al may be about 200 nm. The resist mask and Ta/Al deposited thereon are removed by the lift-off method. The Si substrate 1 is heat-treated in, for example, a nitrogen atmosphere at a temperature of 400° C. to 1,000° C., for example, about 600° C. and remaining Ta/Al comes into ohmic contact with the electron supply layer 2d. Ohmic contact may be established without the heat treatment. The source electrode 4 and the drain electrode 5, in which the electrode recesses 2A and 2B are filled with a part of the electrode material, are formed.

As illustrated in FIG. 2D, an electrode recess 2C for a gate electrode is formed in the compound semiconductor laminate structure 2. A resist is applied to the compound semiconductor laminate structure 2. The resist is processed by lithography, so that an opening to expose the position to be provided with the gate electrode, for example, the surface of the compound semiconductor laminate structure 2 corresponding to the position to be provided with the electrode is formed in the resist. A resist mask having the opening is formed.

The cap layer 2e and a part of the electron supply layer 2d corresponding to the positions to be provided with the electrode are removed through dry etching using the resist mask. Consequently, the electrode recess 2C is formed by digging the cap layer 2e and a part of the electron supply layer 2d. An inert gas, e.g., Ar, and a chlorine based gas, e.g., Cl₂, may be used as an etching gas. As for the etching condition, for example, the flow rate of Cl₂ is set at 30 sccm, the pressure is set at 2 Pa, and the RF input electric power is set at 20 W. The electrode recess 2C may be formed by etching the cap layer 2e in partway or be formed by etching up to a deeper place of the electron supply layer 2d. The resist mask is removed by an ashing treatment or the like.

As illustrated in FIG. 2E, a gate insulating film 6 is formed. An insulating material, e.g., Al₂O₃, is deposited on the compound semiconductor laminate structure 2 in such a way as to cover the inside wall surface of the electrode recess 2C. For example, Al₂O₃ having a film thickness of about 2 nm to 200 nm, for example, about 10 nm is formed by an atomic layer deposition (ALD) method. Consequently, the gate insulating film 6 is formed.

Deposition of Al₂O₃ may be performed by, for example, a plasma CVD method, a sputtering method, or the like instead of the ALD method. As for the gate insulating film 6, a nitride or an oxynitride of Al may be used instead of Al₂O₃. Oxides, nitrides, or oxynitrides of Si, Hf, Zr, Ti, Ta, or W may be used, or a multilayer structures selected from these materials may be used.

As illustrated in FIG. 2F, a gate electrode 7 is formed. A resist mask to form the gate electrode and a field plate electrode is formed. For example, a canopy structure two-layer resist suitable for the evaporation method and the lift-off method is used. The canopy structure two-layer resist is applied to the gate insulating film 6 and each opening to expose the portion of the electrode recess 2C of the gate insulating film 6 is formed. Consequently, the resist mask having the openings is formed.

An electrode material, e.g., Ni/Au, is deposited on the resist mask and in the opening to expose the electrode recess 2C portion of the gate insulating film 6 by, for example, the evaporation method using the resist mask. The thickness of Ni may be about 30 nm, and the thickness of Au may be about 400 nm. The resist mask and Ni/Au deposited thereon are removed by the lift-off method. The electrode recess 2C is filled with a part of the electrode material with the gate insulating film 6 therebetween to form the gate electrode 7.

An interlayer insulating film is formed, a wiring coupled to the source electrode 4, the drain electrode 5, or the gate electrode 7 is formed, an upper layer serving as a protective film is formed, and a connection electrode exposed at the outermost surface is formed, so that the AlGaN/GaN HEMT is formed.

A MIS type AlGaN/GaN HEMT having the gate insulating film 6 may be formed. A Schottky type AlGaN/GaN HEMT may be formed, in which the gate electrode 7 having no interlayer insulating film 6 is in direct contact with the compound semiconductor laminate structure 2. A gate recess structure in which the gate electrode 7 is formed in the electrode recess 2C may not be adopted. The gate electrode may be formed on the compound semiconductor laminate structure 2, which has no recess, with a gate insulating film therebetween or directly.

In the operation S2, each compound semiconductor element, for example, a compound semiconductor chip, is cut from the Si substrate including the AlGaN/GaN HEMT manufactured in the operation S1. The Si substrate is diced along a dicing line provided on the substrate by using, for example, a certain laser and each compound semiconductor element is cut.

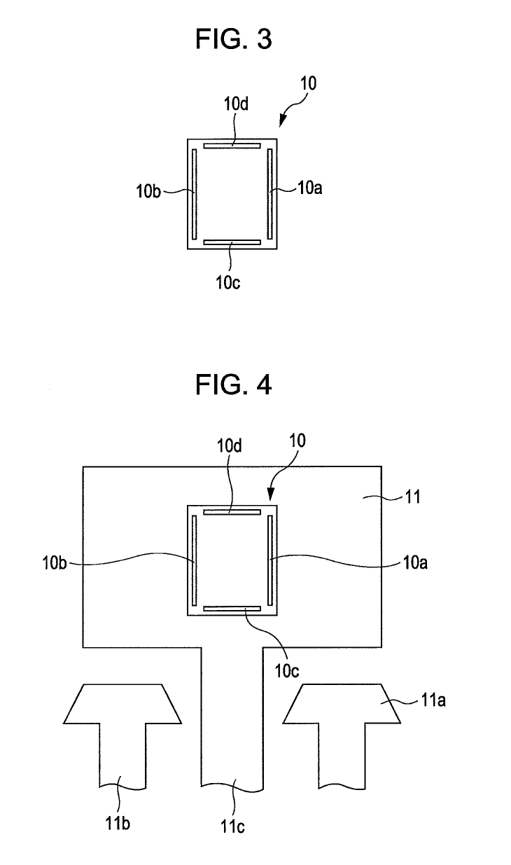

FIG. 3 illustrates an exemplary compound semiconductor element. The compound semiconductor element illustrated in FIG. 3 may be manufactured by the production process illustrated in FIGS. 2A to 2F. As for connection electrodes, a source pad 10a is formed along one side of the rectangular outer edge on the surface of the compound semiconductor element 10, a gate pad 10b is formed along another side, and drain pads 10c and 10d are formed along remaining two sides. The source pad 10a is coupled to the source electrode through a wiring and the like in a lower under the compound semiconductor element 10. The gate pad 10b is coupled to the gate electrode through a wiring and the like in a layer under the compound semiconductor element 10. The drain pads 10c and 10d are coupled to the drain electrode through a wiring and the like in a layer under the compound semiconductor element 10.

FIG. 4 illustrates an exemplary lead frame. In the operation S3, as illustrated in FIG. 4, the compound semiconductor element 10 is disposed on the lead frame 11. An adhesive material having an excellent heat dissipation effect, e.g., a solder paste of molten metal, serving as a die bonding material 12 is applied to the lead frame 11 integrated with a drain lead 11c and, then, the compound semiconductor element 10 is disposed. The die bonding material 12 is melted through heating, and the compound semiconductor element 10 is bonded to the lead frame 11 with the die bonding material 12 therebetween through cooling.

In order to make the semiconductor package low-profile, there is a difference in height between the surface of the lead frame 11 and the surface of the source lead 11a. There is a difference in height between the back of the lead frame 11 and the back of the source lead 11a. The compound semiconductor element 10 is disposed on the lead frame 11 and, therefore, a difference in height between the surfaces of the lead frame 11 and the source lead 11a may be reduced. There is a difference in height between the surface of the lead frame 11 and the surface of the gate lead 11b. There is a difference in height between the back of the lead frame 11 and the back of the gate lead 11b. The compound semiconductor element 10 is disposed on the lead frame 11 and, therefore, a difference in height between the surfaces of the lead frame 11 and the gate lead 11b may be reduced. There is a difference in height between the surface of the lead frame 11 and the surface of the drain lead 11c integrated with the lead frame 11. There is a difference in height between the back of the lead frame 11 and the back of the drain lead 11c. The compound semiconductor element 10 is disposed on the lead frame 11 and, therefore, a difference in height between the surfaces of the lead frame 11 and the drain lead 11c may be reduced.

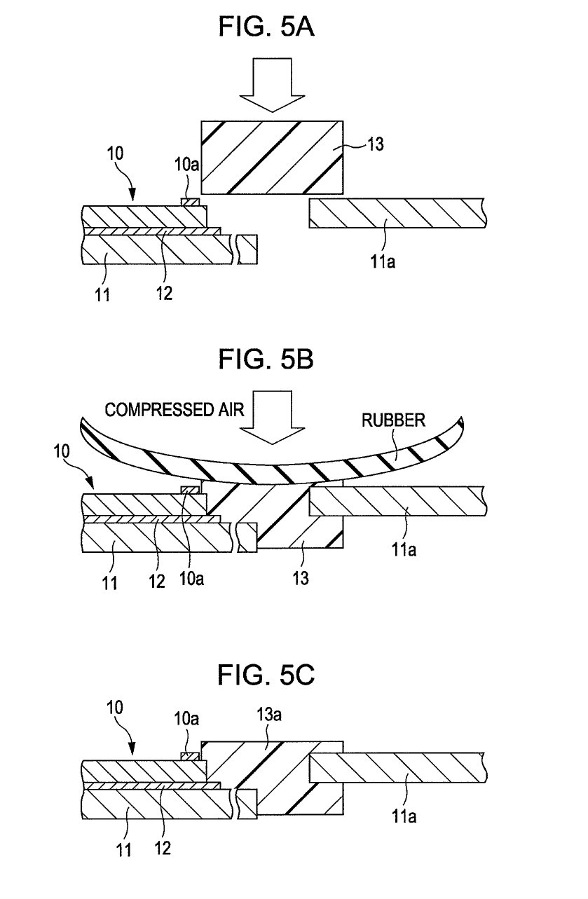

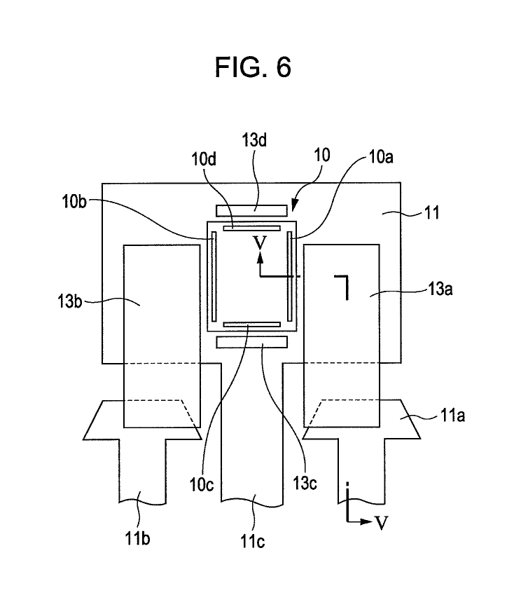

FIG. 5A to FIG. 5C illustrate an exemplary formation of an auxiliary layer. In the operation S4 illustrated in FIG. 1, an auxiliary layer 13a is formed. FIG. 6 illustrates an exemplary auxiliary layer. In FIG. 6, the auxiliary layers 13a, 13b, 13c, and 13d are disposed. FIGS. 5A to 5C illustrate a section taken along a broken line V-V illustrated in FIG. 6. As illustrated in FIG. 5A, a resin film 13 is stuck between the source pad 10a of the compound semiconductor element 10 and the source lead 11a. The resin film 13 is stuck between the gate pad 10b of the compound semiconductor element 10 and the gate lead 11b. The resin film 13 is stuck between the drain pad 10c of the compound semiconductor element 10 and the drain lead 11c. The resin film 13 is stuck between the drain pad 10d of the compound semiconductor element 10 and the lead frame 11. As for the resin film 13, a film in a semi-cured state of a heat-resistant resin, e.g., an epoxy resin or a polyimide resin, may be used.

As illustrated in FIG. 5B, the resin film 13 is pressurized with 2 kg to 5 kg per auxiliary layer by a device, e.g., a mounter, so that the resin film 13 is stuck temporarily. After temporary sticking, the temperature is set at 150° C., the pressure is set at 0.5 MPa, and the resin film 13 is pressurized for about 30 seconds with a vacuum laminator.

As illustrated in FIG. 5C, the resin film 13 is fully cured. A gap between the source pad 10a, the lead frame 11, and the source lead 11a is filled with the resin and, thereby, the auxiliary layer 13a having a flat surface is formed. A gap between the gate pad 10b, the lead frame 11, and the gate lead 11b is filled with the resin and, thereby, the auxiliary layer 13b having a flat surface is formed. A gap between the drain pad 10c, the lead frame 11, and the drain lead 11c is filled with the resin and, thereby, the auxiliary layer 13c having a flat surface is formed. A gap between the drain pad 10d and the lead frame 11 is filled with the resin and, thereby, the auxiliary layer 13d having a flat surface is formed.

The auxiliary layers 13a, 13b, 13c, and 13d are formed with the vacuum laminator without generating voids and the like. The vacuum laminator treats a plurality of lead frames in one operation and, therefore, the productivity may be improved. The resin film 13 may be cured completely.

The auxiliary layers 13a, 13b, 13c, and 13d may be formed by other methods. For example, a resin may be applied to an optional position with a jet dispenser produced by Musashi Engineering, Inc. The jet dispenser may coat even a place having a large area and a surface with a height difference in a short time.

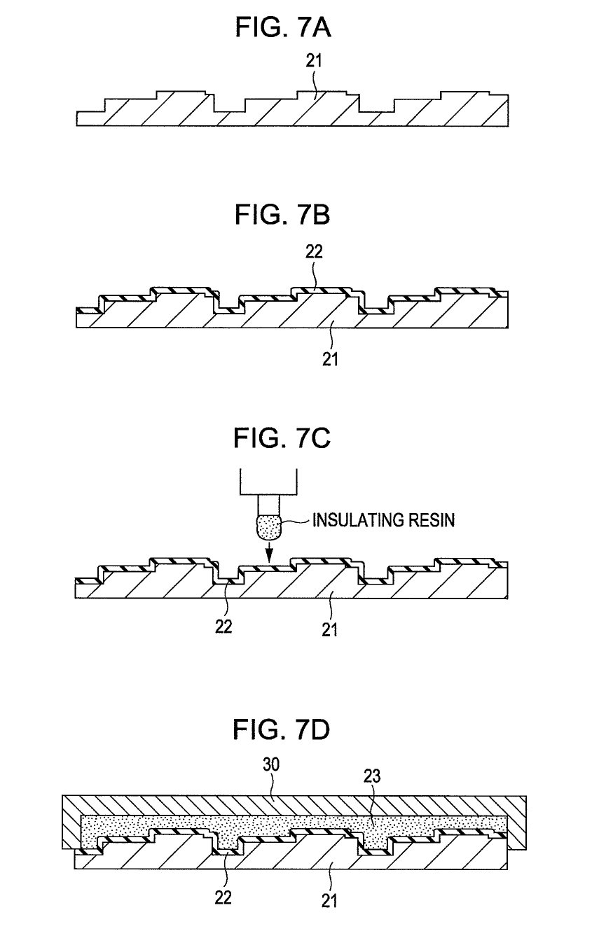

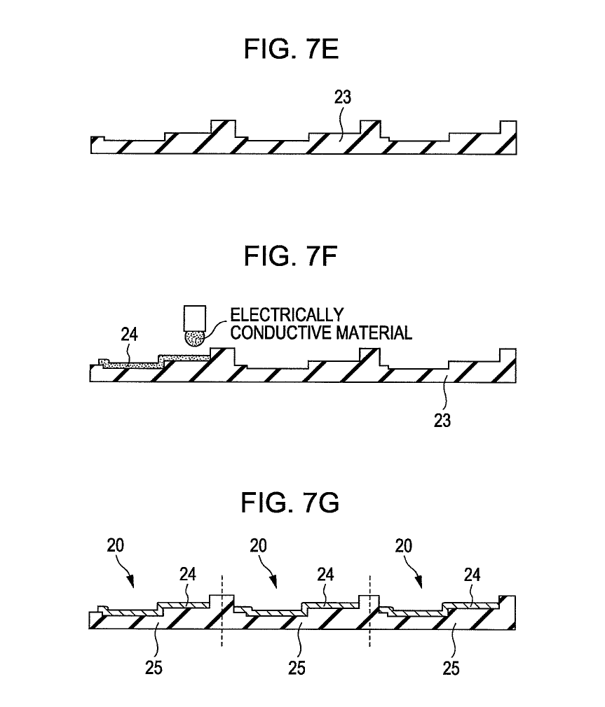

FIG. 7A to FIG. 7G illustrate an exemplary formation of a seal layer. In the operation S5 illustrated in FIG. 1, a seal layer 20 of the compound semiconductor element 10 is formed. As illustrated in FIG. 7A, a structure 21 having a surface with height difference is formed. The height difference on the surface of the structure 21 may correspond to the height difference on the surface of the structure in which, for example, the fixed compound semiconductor element 10, the auxiliary layers 13a, 13b, 13c, and 13d, the lead frame 11 including the drain lead 11c, the source lead 11a, and the gate lead 11b are disposed. In the case where the height difference of the structure 21 is represented by A and the height difference of the structure including the compound semiconductor element 10 and the like is represented by B, the height difference A on the surface of the structure 21 may have the shape engaging with the height difference of the height difference B.

As illustrated in FIG. 7B, a mold release agent 22 is applied to the surface of the structure 21. As for the mold release agent 22, for example, a fluorine based resin may be used. As illustrated in FIG. 7C, an insulating resin serving as a mold resin is supplied to the surface of the structure 21 with the mold release agent 22 therebetween.

As illustrated in FIG. 7D, the surface of the structure 21 is covered with the insulating resin 23 with the mold release agent 22 therebetween, and the shape of the insulating resin 23 is adjusted by a molding member 30. In this state, for example, a heat treatment at a temperature of about 120° C. is performed for about 30 minutes, so that the insulating resin 23 is made into a semi-cured state. As illustrated in FIG. 7E, the insulating resin 23 molded by the structure 21 is peeled off the mold release agent 22 of the structure 21.

As illustrated in FIG. 7F, an electrically conductive material is supplied to certain places of the surface of the insulating resin 23. As for the electrically conductive material, an electrically conductive adhesive material, e.g., a Ag paste or a Cu paste, may be used. The electrically conductive material may be supplied with a jet dispenser. For example, the thickness of the electrically conductive material may be about 10 μm to 30 μm and be uniform. A connection electrically conductive film 24 is formed on the surface of the insulating resin 23. An ink jet method may be used instead of the jet dispenser.

The connection electrically conductive film may be formed by a plating method. A plating seed electrode is formed on the surface of the insulating resin 23, and a resist is applied to the seed electrode. An opening is formed at a position to be provided with the connection electrically conductive film of the resist and a part of the seed electrode is exposed. For example, a Cu electrolytic plating layer having a thickness of about 10 μm to 30 μm is formed on the seed electrode in the opening by an electrolytic plating treatment. The resist is peeled and the electrolytic plating layer is etched. A Ni/Au electroless plating layer is formed on the electrolytic plating layer by an electroless plating treatment. For example, Ni may have a thickness of about 2 μm to 5 μm, and Au may have a thickness of about 0.01 μm to 0.5 μm. Consequently, the connection electrically conductive film having a laminate structure of Cu/Ni/Au is formed.

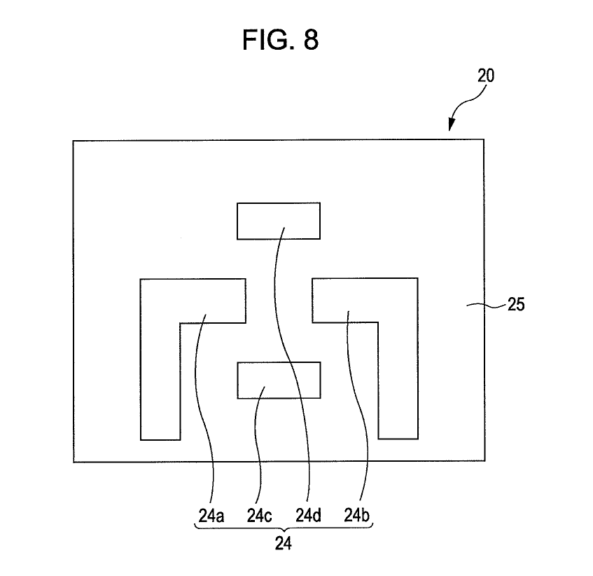

As illustrated in FIG. 7G, the insulating resin 23 is cut along broken lines in the drawing, so that the structure is made into individual pieces. A seal layer 20 having the connection electrically conductive film 24 on the surface is formed. FIG. 8 illustrates an exemplary seal layer. As illustrated in a plan view of FIG. 8, regarding the seal layer 20, the connection electrically conductive film 24 is formed on the surface of a resin layer 25 including the insulating resin. The connection electrically conductive film 24 may include electrically conductive films 24a, 24b, 24c, and 24d. The electrically conductive film 24a electrically couples the source pad 10a and the source lead 11a. The electrically conductive film 24b electrically couples the gate pad 10b and the gate lead 11b. The electrically conductive film 24c electrically couples the drain pad 10c and the drain lead 11c. The electrically conductive film 24d electrically couples the drain pad 10d and the lead frame 11.

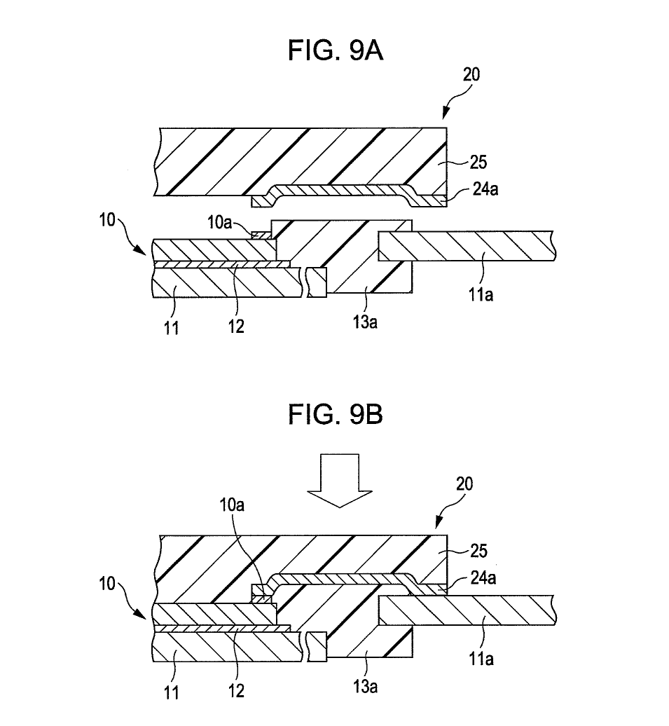

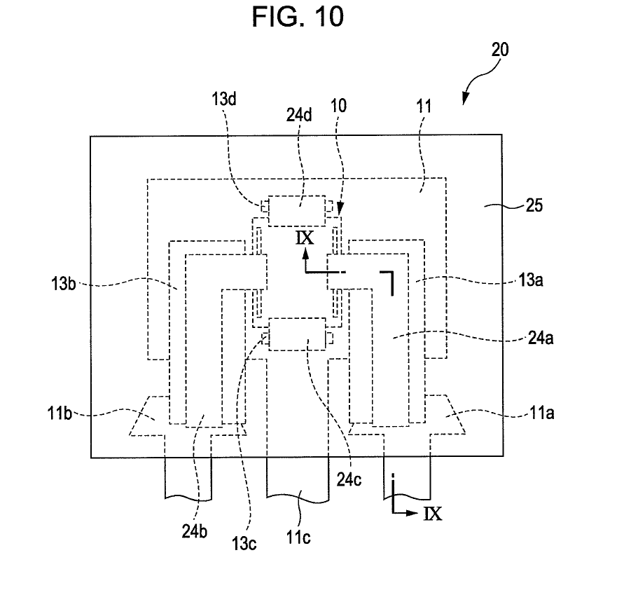

FIG. 9A and FIG. 9B illustrate an exemplary bonding of a seal layer. In the operation S6 illustrated in FIG. 1, the seal layer 20 is bonded to the lead frame 11. FIG. 10 illustrates an exemplary seal layer. FIG. 9A and FIG. 9B illustrate a section taken along the broken line IX-IX illustrated in FIG. 10. As illustrated in FIG. 9A, the seal layer 20 is aligned with the lead frame 11, to which the compound semiconductor element 10 has been fixed, by using a device, e.g., a mounter or a die bonder. The surface shape of the electrically conductive film 24a engages with the surface shape including the source pad 10a, the lead frame 11, the source lead 11a, and the auxiliary layer 13a filling a gap between them. The surface shape of the electrically conductive film 24b engages with the surface shape including the gate pad 10b, the lead frame 11, the gate lead 11b, and the auxiliary layer 13b filling a gap between them. The surface shape of the electrically conductive film 24c engages with the surface shape including the lead frame 11, the drain lead 11c, and the auxiliary layer 13c filling a gap between them. The surface shape of the electrically conductive film 24d engages with the surface shape including the drain pad 10d, the lead frame 11, and the auxiliary layer 13d filling a gap between them.

In this state, as illustrated in FIG. 9B, for example, the temperature is set at about 180° C., the pressure is set at about 1 MPa to 5 MPa, and heating and pressurization are performed for about 30 minutes. The insulating resin of the resin layer 25, the electrically conductive material of the connection electrically conductive film 24, and the resin of the auxiliary layers 13a, 13b, 13c, and 13d are cured. Electrically conductive fillers in the electrically conductive material of the connection electrically conductive film 24 may come into contact with each other and, thereby, the electrical conductivity may be exerted. The source pad 10a and the source lead 11a are electrically coupled through the electrically conductive film 24a. The gate pad 10b and the gate lead 11b are electrically coupled through the electrically conductive film 24b. The drain pad 10c and the drain lead 11c are electrically coupled through the electrically conductive film 24c. The drain pad 10d and the lead frame 11 are electrically coupled through the electrically conductive film 24d. Consequently, a semiconductor package is formed.

The connection electrically conductive film 24 including the wide electrically conductive films 24a to 24d and having a large area becomes electrically continuous, so that the connection resistance may be reduced and a large current may pass. The auxiliary layers 13a, 13b, 13c, and 13d are formed in advance in such a way as to fill the gaps between the lead frame 11 and the individual leads 11a to 11d, and the connection electrically conductive film 24 is coupled to the auxiliary layer. The surface shape of the seal layer 20, which may reduce the connection distances between the electrodes and the number of connection places, is formed into the shape corresponding to surface height differences in the lead frame 11 side and, therefore, a low-profile semiconductor package is manufactured by filling the connection electrically conductive film 24 into the seal layer 20. Connection between the individual electrodes and sealing of the compound semiconductor element 10 by the mold resin are performed in one operation and, thereby, the process may be reduced.

The connection resistance between the electrodes is reduced, the connection distances between the electrodes or the number of connection places is reduced, and a low-profile semiconductor package is manufactured in a reduced process.

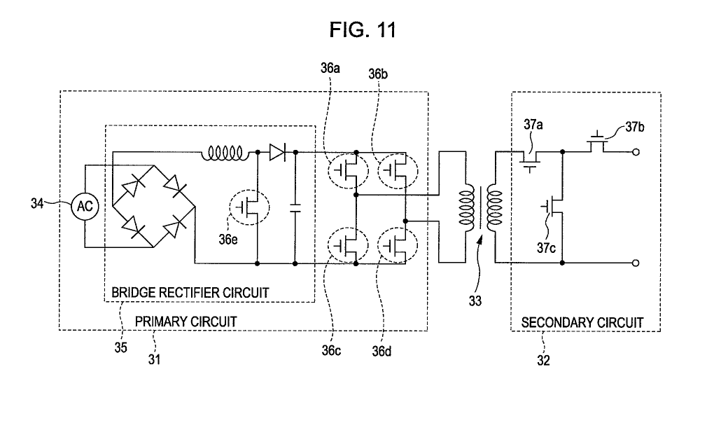

FIG. 11 illustrates an exemplary power supply device. The power supply device illustrated in FIG. 11 may include the semiconductor package manufactured by the manufacturing process illustrated in FIG. 1.

The power supply device includes a high-voltage primary circuit 31, a low-voltage secondary circuit 32, and a transformer 33 disposed between the primary circuit 31 and the secondary circuit 32. The primary circuit 31 includes an alternating-current power supply 34, a so-called bridge rectifier circuit 35, and a plurality of, for example, four switching elements 36a, 36b, 36c, and 36d. The bridge rectifier circuit 35 includes a switching element 36e. The secondary circuit 32 includes a plurality of, for example, three switching elements 37a, 37b, and 37c.

The switching elements 36a, 36b, 36c, 36d, and 36e of the primary circuit 31 may be, for example, the compound semiconductor element AlGaN/GaN HEMT manufactured in the operation S1 illustrated in FIG. 1. The switching elements 37a, 37b, and 37c of the secondary circuit 32 may be the MIS FET including silicon.

The connection resistance between the electrodes is reduced, the connection distances between the electrodes or the number of connection places is reduced, and a low-profile semiconductor package is used for the high-voltage circuit. Consequently, a power circuit exhibiting high reliability and having a large power may be provided.

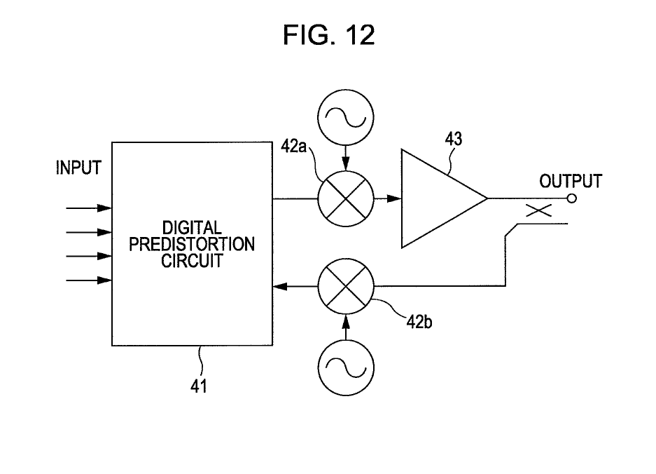

FIG. 12 illustrates an exemplary high-frequency amplifier. The high-frequency amplifier illustrated in FIG. 12 may include the semiconductor package manufactured by the manufacturing process illustrated in FIG. 1.

The high-frequency amplifier includes a digital predistortion circuit 41, mixers 42a and 42b, and a power amplifier 43. The digital predistortion circuit 41 compensates an input signal for nonlinear distortion. The mixer 42a performs mixing of the input signal compensated for nonlinear distortion and the alternating-current signal. The power amplifier 43 amplifies the input signal mixed with the alternating-current signal and includes, for example, the compound semiconductor element AlGaN/GaN HEMT manufactured in the operation S1 illustrated in FIG. 1. For example, based on switching of the switch, the signal in the output side is mixed with the alternating-current signal by the mixer 42b, and the mixed signal is output to the digital predistortion circuit 41.

The connection resistance between the electrodes is reduced, the connection distances between the electrodes or the number of connection places is reduced, and a low-profile semiconductor package is used for the high-frequency amplifier. Consequently, a high-frequency amplifier exhibiting high-reliability and having a high-breakdown voltage may be provided.

Example embodiments of the present invention have now been described in accordance with the above advantages. It will be appreciated that these examples are merely illustrative of the invention. Many variations and modifications will be apparent to those skilled in the art.

1. A method for manufacturing a semiconductor device, comprising:
placing a seal layer including a connection conductive film on the surface so that the connection conductive film is in contact with an electrode of a semiconductor element and a lead;
electrically coupling the electrode and the lead through the connection conductive film; and
sealing the semiconductor element by the seal layer.

2. The method for manufacturing a semiconductor device according to claim 1, further comprising,
forming an auxiliary layer to fill a gap between the electrode and the lead.

3. The method for manufacturing a semiconductor device according to claim 2,
wherein the auxiliary layer has a substantially flat surface.

4. The method for manufacturing a semiconductor device according to claim 2,
wherein the auxiliary layer includes a heat-resistant resin.

5. The method for manufacturing a semiconductor device according to claim 2, further comprising,
press-contacting film to the electrode and the lead.

6. The method for manufacturing a semiconductor device according to claim 1, further comprising,
forming the connection conductive film using a jet dispenser.

7. The method for manufacturing a semiconductor device according to claim 1, further comprising,
forming the connection conductive film by a plating method.

8. The method for manufacturing a semiconductor device according to claim 1, further comprising:
forming the seal layer using a structure engaging with a shape of the surface; and
removing the structure.

9. The method for manufacturing a semiconductor device according to claim 1,
wherein the semiconductor element includes a compound semiconductor element.

10. A semiconductor device comprising:
a lead and a lead frame having a difference in height between the surfaces between the lead and the lead frame;
a compound semiconductor element, provided on the lead frame, including an electrode;
an auxiliary layer for filling a gap between the electrode, the lead, and the lead frame;
a connection conductive for electrically coupling the electrode and the lead via the auxiliary layer; and
a seal layer for sealing the semiconductor element.

11. The semiconductor device according to claim 10,
wherein the auxiliary layer has a substantially flat surface.

12. The semiconductor device according to claim 10,
wherein the semiconductor element includes a compound semiconductor element.

13. The semiconductor device according to claim 10,
wherein the auxiliary layer includes a heat-resistant resin.

14. An electronic circuit comprising:
a semiconductor device including:
a lead and a lead frame having a difference in height between the surfaces between the lead and the lead frame;
a compound semiconductor element, provided on the lead frame, including an electrode;
an auxiliary layer for filling a gap between the electrode, the lead, and the lead frame;
a connection conductive for electrically coupling the electrode and the lead via the auxiliary layer; and
a seal layer for sealing the semiconductor element.

15. An electrical circuit according to claim 14, wherein
the electrical circuit includes at least one of a high-frequency amplifier to amplify a high-frequency voltage input and a power supply circuit including a transformer, a high-voltage circuit and a low-voltage circuit.
